(19) United States
(12) Patent Application Publication
(10) Pub. No.: US 2005/0272175 A1
(43) Pub. Date: Dec. 8, 2005

(54) Laser structuring for manufacture of thin film silicon solar cells

(76) Inventors: Johannes Meier, Corcelles (CH); Richard Grundmuller, Munchen (DE)

Correspondence Address: PEARNE & GORDON LLP, 1801 EAST 9TH STREET, SUITE 1200, CLEVELAND, OH, 44114-3108, US

(21) Appl. No.: 11/141,620

(22) Filed: May 31, 2005

Related U.S. Application Data
(60) Provisional application No. 60/576,142, filed on Jun. 2, 2004.

(51) Int. Cl. H01L 21/00

(52) U.S. Cl. 438/22

(57) ABSTRACT

A method of manufacturing thin-film, series connected silicon solar cells having a ZnO TCO layer, for example, using an ultraviolet scribing laser to scribe said ZnO TCO layer to form relatively smooth walls through said TCO layer.

### CROSS-REFERENCES TO RELATED APPLICATIONS

This application claims the benefit of provisional application Ser. No. 60/576,142, filed on Jun. 2, 2004, incorporated herein by reference.

### BACKGROUND OF THE INVENTION

This application relates generally to a solar cell and its method of manufacture. More specifically, this application relates to a method of manufacturing thin-film, series connected silicon solar cells using an ultraviolet scribing laser.

Thin film solar cells having monolithic series interconnections can be formed by using laser or mechanical structuring. Mechanical structuring can include photolithographic or chemical etching structuring. The structuring is useful to form large-area photovoltaic (PV) modules or “arrays”. These concepts allow the PV modules to be adapted to the desired output characteristics—V_{OC} (open circuit voltage), I_{SC} (short-circuit-current) and FF (fill factor—defined as the maximum power produced at the maximum power point, divided by the product of I_{SC} and V_{OC}, which is always less than 1). Thus, these features can be specifically tailored to the needs/applications of the user.

A method of manufacture using scribing lasers is disclosed in U.S. Pat. No. 4,292,092, incorporated herein by reference. This reference suggests using a continuously excited, neodymium, Yttrium Aluminum Garnet (CW Nd:YAG) laser for scribing a transparent conductive oxide (TCO) layer deposited on a non-conductive substrate. Two or more active layers are deposited on the TCO layer, and are also laser scribed. A back electrode layer is deposited on the active layers, and optionally scribed. The laser of the reference has a wavelength of about 1060 nanometers.

Similarly, referring to FIG. 2 for illustration, for p-i-n configured thin film silicon solar cells, the structuring of the three scribes can be performed using lasers for cutting the active layers and outer electrode layers into “trench” cuts 26 and 27, typically by using a 532 nm Nd:YAG or Nd:YVO₄ laser. In contrast, for cutting the TCO layer at trench cut 25, a 1064 nm Nd:YAG or Nd:YVO₄ laser is used. Alternatively, in the case of a SnO₂ TCO, the 532 nm laser may be applied.

The resulting “trench” cuts are scribed laser cuts made through and along a given layer material to expose an underlying material, with the objective of separating the scribed layer material into two or more portions, for example, as in defining and separating the layer material into separate individual solar cells on a given module. Thus, the scribed layer material portions can be electrically isolated from each other via the trenches if the underlying material is non-conductive.

Furthermore, in the case of LP-CVD (low pressure chemical vapor deposition) ZnO fabrication of the TCO layer, use of the 1064 nm lasers for the realization of functioning, large-area a-Si:H (amorphous hydrogenated silicon) anhydrous-based PV modules has not been commercially successful.

The slightly higher absorption of laser energy by the ZnO using a 1064 nm laser (1064 nm˜1.16 eV), due to free carrier absorption, could be an improvement compared to the lesser absorption using a laser wavelength of 532 nm (corresponding to 2.3 eV), because at the weaker absorption by ZnO at 532 nm, good scribe conditions were not achieved for scribing the ZnO TCO, with respect to isolation and quality of the borders of the scribe trenches. Thus, use of 532 nm lasers did not lead to a high fill factor of the module, as desired, and thus were not useful for scribing a ZnO TCO layer.

However, FIGS. 1A, 1B, and 1C highlight two problems resulting from the structuring of the ZnO TCO scribes using the 1064 nm scribing laser: (1) the difficulty of realizing an electrical isolation of the TCO segments of at least several 100 kΩ/meter and (2) the lack of quality of the edges of the resulting trench cuts.

Good electrical isolation is desired in order to achieve a high performance of the PV modules. FIGS. 1A, 1B, and 1C show the typical bulges on the edges of the TCO scribe trenches using a 1064 nm optimized laser cut of ZnO. One might get good isolation, although the edges of the trench result in beads and/or bulges which undesirably reduce the fill factor of the module, as discussed above. The low quality of the TCO scribe trench edges using the 1064 nm laser scribing techniques has a strong influence in giving rise to manufacturing short-circuits (shunts). These short-circuits can then lead to a dramatic and undesirable loss in the efficiency of the modules. The texture of the borders of the TCO scribe trench edges, in the case of ZnO TCOs, for example, strongly influences the fill factor (FF) of the module. Sharp, molten, and uneven edges, as shown in FIGS. 1A-1C, which give rise to the shunts, thereby lower the fill factor due to the short circuits. Thus, the use of 1064 nm laser scribing cannot be effectively applied even when a good isolation is achieved.

Accordingly, in case of ZnO as the front TCO layer, the challenge is to realize high quality border edges of the resulting trenches, thereby resulting in the desirable high FF with the desirable high isolation at the TCO scribe trenches. Because the structuring of ZnO using lasers at 1064 nm wavelength result in undesirable burn-outs, the use of ZnO for the TCO layer has been unsatisfactory, because the borders of the trench cuts through ZnO using the 1064 nm laser resulted in the irregular bulges or beads with a sharp texture, as discussed above, compared to as-grown textured LP-CVD ZnO.

A further disadvantage of the use of the 1064 nm laser scribing process was the low process speed of the cutting (scribing) velocities, which were typically below 10 m/min. An additional disadvantage was the wide trench width, which is typically larger than 20 μm, leading to wasted space. These disadvantages make the overall module less efficient than it could be.

The above described shortcomings are likely reasons why ZnO has not been successfully applied as a front TCO contact in the past. It would be beneficial to provide a manufacturing process that can help overcome one or more of the above described shortcomings to allow the economically successful use of ZnO as the TCO layer in thin-film solar cell PV modules.

### BRIEF SUMMARY OF THE INVENTION

Provided is a method for manufacturing a thin-film solar cell comprising the steps of:
providing a conducting layer on a substrate;
applying a laser beam to the conducting layer to scribe portions of the conducting layer through to the substrate to form a trench through and along some portion of the conducting layer, wherein a substantial portion of the energy of the laser is absorbed by the conducting layer, such that the applying evaporates a substantial portion of the conducting layer in contact with the laser beam to form substantially smooth walls of the trench;
providing one or more active layers over the conducting layer, and
providing an additional conducting layer on the one or more active layers.

Also provided is a method for manufacturing a thin-film solar cell comprising the steps of:
providing a conducting layer including ZnO on a substrate;
applying an ultraviolet laser beam to the conducting layer to scribe portions of the conductor layer through to the substrate to form a trench through and along some portion of the conducting layer;
providing one or more active layers over the conducting layer, and
providing an additional conducting layer on the one or more active layers.

Still further provided is a solar module comprising a substrate and a first conducting layer including ZnO covering some portion of the substrate. The conducting layer has a plurality of first trenches scribed through to the underlying substrate to form a plurality of separate conducting layer portions from the conducting layer separated from each other by the plurality of first trenches.

The above solar module also comprises one or more active layers covering some portion of the conducting layer, where one or more active layers has a plurality of second trenches scribed through to the underlying conducting layer to form a plurality of separate active layer portions from the one or more active layers separated from each other by the plurality of second trenches, and wherein each of the plurality of separate active layer portions covers a portion of a corresponding one of the plurality of separate conducting layer portions.

The above solar module also comprises a plurality of separate second conducting layers each covering some portion of a corresponding one of the separate active layer portions. A plurality of series connected solar cells on the substrate each include one of the separate second conducting layers, the corresponding one of the separate active layer portions and the corresponding one of the separate first conducting layer portions. The resulting solar cells are series connected by electrically connecting the second conducting layer of one of the solar cells to the first conducting layer portion of an adjacent one of the solar cells.

### BRIEF DESCRIPTION OF THE SEVERAL VIEWS OF THE DRAWINGS

The features and advantages of the present invention will become apparent to those skilled in the art to which the present invention relates upon reading the following description with reference to the accompanying drawings, in which:

FIGS. 1A-1C are a series of photographs showing consecutively closer views of ZnO TCO scribe trenches by using the prior art scribing techniques;

FIG. 2 is a schematic drawing of a thin-film series connected solar cell configuration for illustrative purposes;

FIG. 3 is a plot showing the experimentally measured absorption of LP-CVD by a ZnO TCO layer using a scribing technique of the invention;

FIG. 4A is a photograph of a top view and 4B is a photograph of a side view of ZnO TCO scribe trenches resulting from the application of a scribing technique of the invention;

FIGS. 5A and 5B are consecutively closer photographs of three laser scribe patterns, 355 nm, bottom trench, and 532 nm, mid and top trenches, performed along the full 1250 mm length of a KAI 1.4 m2 substrate, according to a process of the invention.

### DETAILED DESCRIPTION OF THE INVENTION

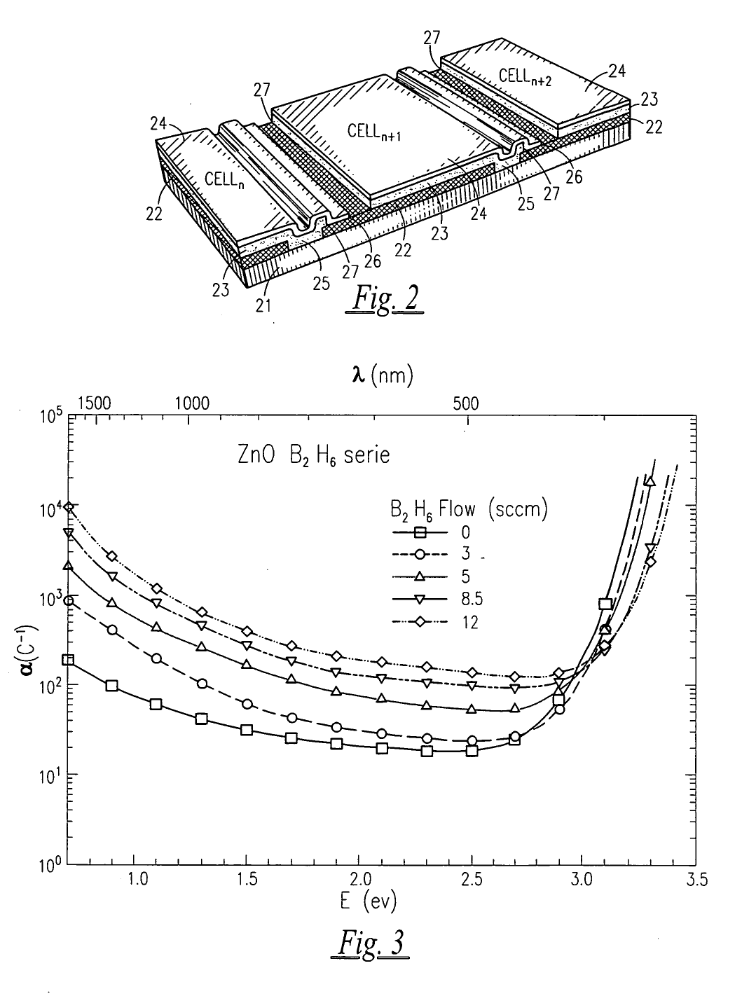

FIG. 2 is a simplified schematic showing a portion of a thin-film, series connected PV module for illustrative purposes. This figure shows three cells (Cellₙ, Cellₙ₊₁, and Cellₙ₊₂) connected in series, although any number of desired cells could be manufactured, and the individual cells could instead be connected in parallel, or not electrically connected together, as desired.

Generally, as shown in FIG. 2, a typically non-conducting substrate 21, which could be of glass, for example, has a first conducting layer 22 provided on the substrate. Then, one or more active layers 23 are provided on the first conducting layer, and an outer electrode layer 24 is provided on the active layers as a second conducting layer. The various layers are separated into separate portions each for use in a separate solar cell by one or more techniques, such as laser scribing the individual layers using a laser beam before the subsequently layer is applied. This results in the trenches 25, 26, and 27 that separate the conducting layer, active layer(s) and second conducting layer, respectively, into the separate solar cells.

The substrate and first conducting layers are typically transparent to allow light to reach the active layer(s) through them, because the semiconducting active layers are transparent enough to let light bass. Furthermore, a back reflector can be applied so that the light is forced to pass a second time through the active layers to be eventually absorbed to enhance efficiency. Alternatively, the second conducting layer could be made transparent to allow light to reach the active layer from that side.

Furthermore, the second conducting layer of one cell is typically electrically connected to the first conducting layer of an adjacent cell by overlapping the second layer on the first layer, in order to series connect the individual solar cells, resulting in a series connected PV module.

Specifically, in the method according to a current embodiment of the invention, a transparent ZnO TCO layer is chosen for the first conducting layer 22, which is deposited on a transparent substrate 21, such as by using an LP-CVD process. Alternatively, a sputtering process might be used to deposit the TCO layer. The transparent substrate of the current embodiment is glass, but other transparent materials such as a highly transparent UV-stable plastic could alternatively be utilized, for example. Then, the ZnO TCO layer is laser scribed using an ultraviolet laser beam through to the substrate 21, forming the trench 25 and differentiating the TCO layers of the separate individual solar cells from each other on the solar module.

One or more active layers are used to form the p-i-n-junction, typically including differently doped and/or undoped silicon layers. For the current embodiment, these active layers are deposited on the ZnO TCO layer, such as by a LP-CVD or PECVD process. This may result in the TCO trench 25 being filled with one or more of the active layers, as shown in FIG. 2. After their application, the active layer(s) are laser scribed down to expose the TCO layer, resulting in trench cut 27 and differentiating the active layer(s) of the separate, individual solar cells.

In the current embodiment, an electrode layer as the additional conducting layer 24 is then applied over the active layer(s) to form the individual outer electrodes of the individual solar cells. The back electrode can be comprised of the TCO or a fully reflective like aluminum or other suitable material. The outer electrodes can be applied using a LP-CVD process (for the current embodiment), although alternative processes, such as sputtering, could also be used. For alternate embodiments, the electrode layers could be individually and separately formed for each cell. However, for the current embodiment, the electrode layer 24 can be applied over the active layers of the entire module, and then laser scribed through to expose the active layer(s) 23, resulting in the trench cut 26 and separating the overall electrode layer into separate electrode layers for each of the separate, individual solar cells.

In the current embodiment, the electrode layer of one cell is overlapped with, and connected to, the TCO layer of an adjacent cell, resulting in a series-connected electrical contact. In this manner, the individual solar cells are thereby series connected to increase the voltage of the resulting PV module.

Alternative structures could be utilized to result in parallel connections, or the cells could be electrically isolated from each other, if desired for alternative embodiments.

The proper arrangements of the three scribe trenches 25, 26, and 27, as shown in FIG. 2, results in the series-connected cells of the solar module of the current embodiment. In FIG. 2, although only three individual cells are shown for convenience, the process is similar for any desired number of series connected cells.

In order to achieve a better quality trench cut of the TCO layer, especially when using ZnO as the TCO layer as in the current embodiment, a new type of laser for performing the scribe operation to form trench 25 is proposed as part of a manufacturing method. Because the ZnO of the current embodiment TCO layer has a much stronger absorption below the 400 nm wavelength than at the 1064 nm wavelength, an ultraviolet Nd:YVO₄ laser (for example, a Coherent AVIA 355-X 10 Watt laser) operating at a wavelength of 355 nm (˜3.5 eV) is applied for the TCO scribing step (see the characteristics of the laser given below).

By using such a short wavelength ultraviolet laser beam on the ZnO TCO layer of the current embodiment, much or most of the laser beam is efficiently absorbed by the ZnO film. This is shown by the experimentally derived plot of FIG. 3, showing the absorption of a LP-CVD formed ZnO layer. The horizontal axis upper scale represents the laser wavelength, and the lower scale represents the equivalent energy of the laser impinging on the TCO layer. Alpha represents a relative absorption coefficient of the laser energy. B₂H₆ (Diborane) is a boron-hydrogen doping gas mixed during TCO (ZnO) application for p-doping in semiconductor processes. The “sccm” (standard cubic centimeters per minute) represents a gas flow measure of the gas. One can see from the figure that the relative absorption of light energy increases essentially on or after 2.9 eV and above. Therefore a 3.2 eV laser is about 100 times more efficient than a 2.5 or 2.0 eV laser.

Using such an ultraviolet laser to form the PV series connected module of the current embodiment results in more efficient melting and evaporation of the ZnO TCO layer in the trench cut down to the bare glass substrate. In fact, such an ultraviolet laser beam doesn't just melt the ZnO material, as often occurred using the prior art lasers (thus forming the undesirable beads and bulges), but the new laser technique actually vaporizes much or all of the ZnO material in contact with the laser beam, resulting in a cleaner cut (reducing or eliminating the undesirable beads and bulges). Therefore, using a high-energy (short wave) ultraviolet laser beam at the appropriate wavelength (to optimize the desired absorption of the laser energy) achieves a high effectivity, and results in a higher FF with proper isolation of the individual cells. Similarly, for materials other than ZnO, choosing the appropriate laser wavelength for high absorption could also provide similar results.

Accordingly, a very good isolation at a high scribe velocity (greater than 10 m/min) may be achieved by using such a short wavelength laser beam for scribing the TCO layer. Experiments have shown that scribe velocities of >20 or even >40 m/min. are possible, with good results. It goes without saying, that higher laser power could allow the method to exceed even these values, but on the other hand this would probably require a resulting increased demand on the precision of the laser beam guidance.

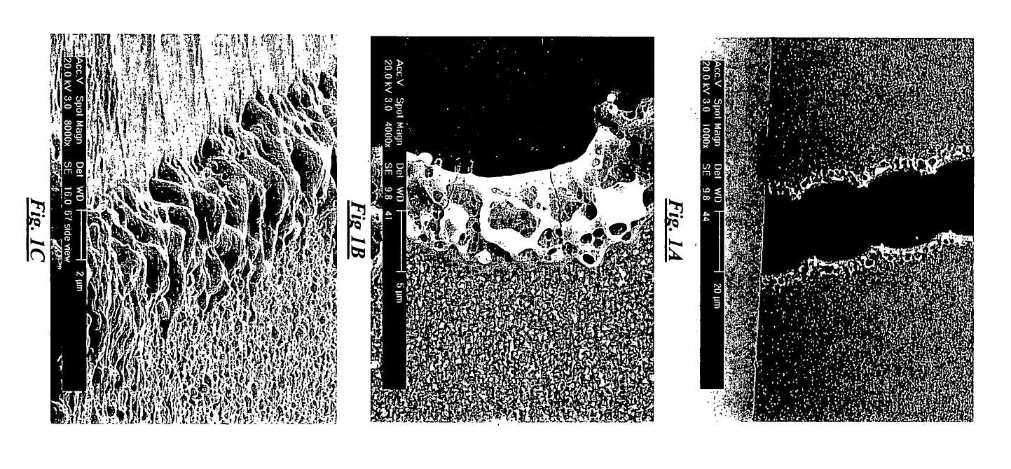

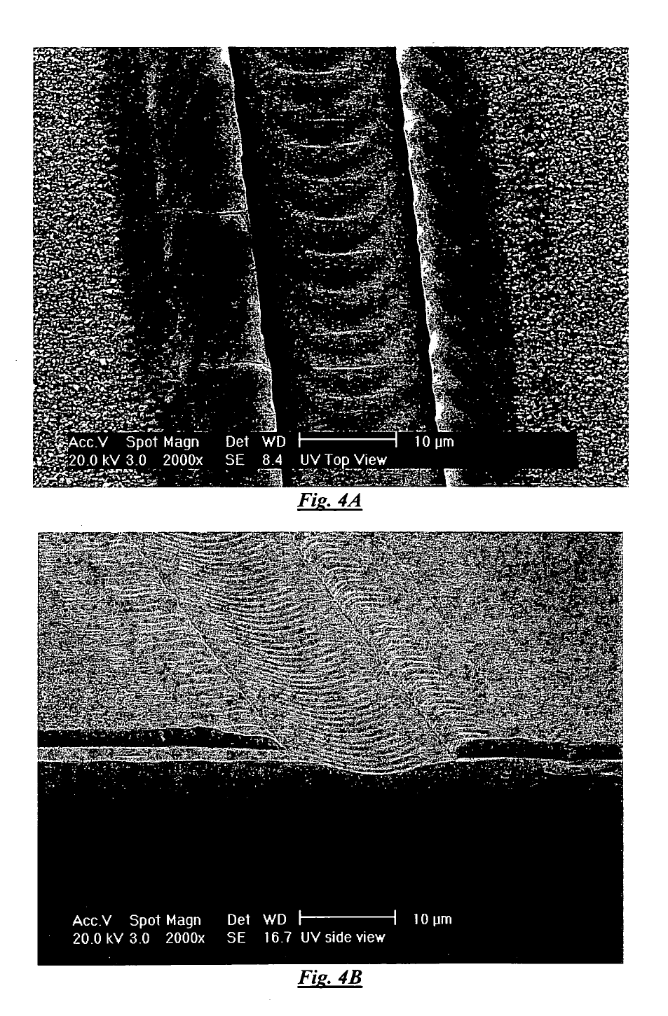

Advantages of using the new laser for scribing the TCO layer are the high quality of the borders of the resulting trench cut: scribing with the 355 nm UV-laser results in borders which are smooth and soft and which run softly down to the glass, minimizing undesirable beads and bulges. There are few or no effects of creating bulges at the edges of the trench (see FIGS. 4A and 4B), in contrast with the case of processes involved when using the 1064 nm wavelength on a ZnO TCO layer (see FIGS. 1A-1C).

FIGS. 4A and 4B are photographic views of a actual UV 355 nm trench cut of an LP-CVD ZnO TCO layer at a thick-ness of 2 μm. FIG. 4A shows a top view and FIG. 4B shows an angled side view of the resulting trench. The Figures show details of the results of the application of the new 355 nm laser scribing process to form the desired trenches through the ZnO TCO layer to the glass substrate. It is clear, when compared with the photographs of FIGS. 1A-1C, that the resulting walls of the trenches using the new 355 nm laser process show that substantially smoother walls are formed on the trenches, and there is less resulting material raised above the TCO layer as compared to the 1064 nm laser process.

Note that FIGS. 4A and 4B, show borders that fall smooth and softly down to the glass, thus forming the desired substantially smooth walls for the TCO trench. The glass is also slightly melted, indicating a high isolation of the trench cuts. Trench widths down to 14 μm can be achieved on 2.3 μm thick ZnO layers with good isolation (several 100 kΩ/m). These desired results are due to a substantial portion of the energy of the laser being absorbed by the ZnO TCO layer during the scribing operation, leading to the evaporation of a substantial portion of the scribed ZnO TCO layer, avoiding the formation of the undesirable beads and bulges shown in FIGS. 1A-1C.

Consequently, these smooth trench edges have the potential in increasing the FF of modules based on ZnO front layer TCO, compared to conventional processes, such as using the 1064 nm laser, for example. Higher FF's, on the other hand, allow for larger segment width and therefore reduced scribe losses and, hence, to principally higher module efficiencies.

Furthermore, a short wavelength light can be focused to a smaller width than a laser operating at longer wavelength. Due to the smaller wavelength of the 355 nm laser of the invention, compared to 1064 nm laser, a smaller trench cut down to 14-15 μm width can be realized with the UV laser, whereas with a 1064 nm laser, trench cut width are in general larger than 20 or 25 μm. The smaller trench cut width at the resulting high isolation allows for a closer positioning of the three scribe lines, as shown in FIGS. 4A and 4B compared to FIGS. 1A-1C, and therefore result in a reduction of the scribe area losses. Such reduced scribe area losses could result in even higher performance of the modules and, thus, could result in higher efficiency.

Known methods for scribing the active and/or electrode layers can be utilized, such as the methods disclosed in U.S. Pat. No. 4,292,092, incorporated herein by reference. For the current embodiment, these layers can be scribed using a 532 nm laser.

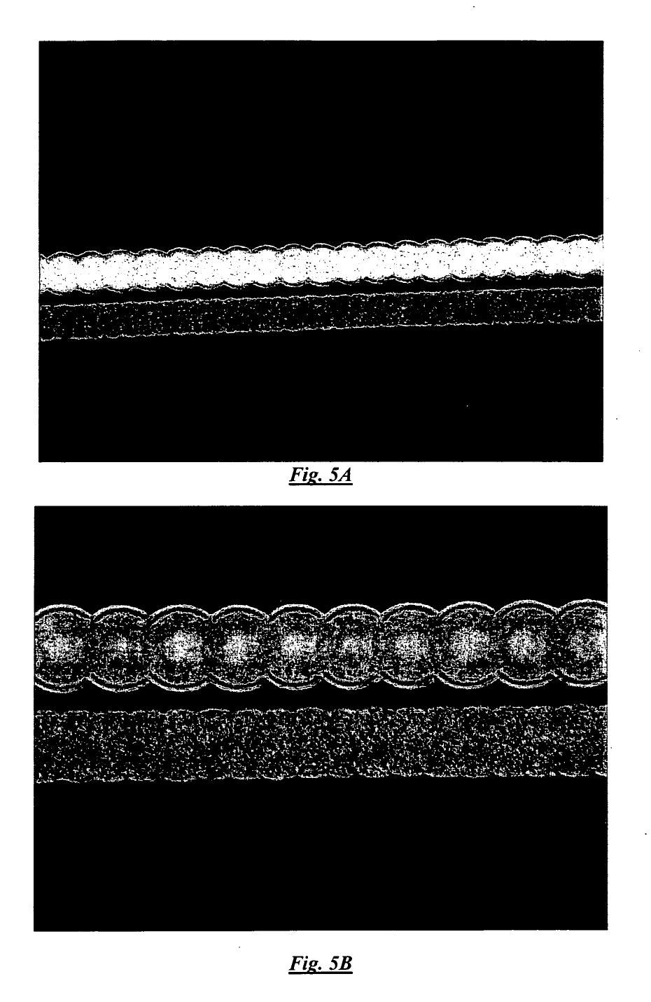

FIGS. 5A and 5B show photographs of all three laser patterns on a sample product by using the method of the invention. The TCO layer, scribed using a 355 nm laser to form the TCO trench, is shown in the bottom trench. The active layer trench is shown as the middle trench, and the electrode layer trench is shown as the top trench, both of which were scribed using a 532 nm laser. These scribing operations were performed along the full 1250 mm length of a KAI 1.4 m2 substrate. All of the three scribe lines shown in the figures lay within a width of about 140 μm, further reducing area losses and increasing efficiencies.

Furthermore, the resulting high scribe velocities of the manufacturing process according to the invention allow for a higher throughput, and therefore could result in a substantial cost reduction of the laser patterning process in the manufacturing of large-area thin film silicon solar cell modules. The higher scribe velocities also help reduce the roughness of the resulting trenches, because the material “next to” the laser beam cut has simply no time to form a bead. For this reason as well, undesirable beads and bulges is reduced.

Acceptable laser parameters for scribing a TCO trench on a film-covered side of a glass substrate coated with ZnO as the TCO layer include a laser power of 8 Watts or more and a scribe velocity of 25 m/min or more. A focusing lens with a focal length of 63 mm can be utilized for focusing the TCO scribing laser.

Example Application:

Specifications of an applied UV-laser (Coherent AVIA 355-X used successfully according to the invention are:

| | |
|---|---|
| Wavelength: | 355 nm |
| Power: | 10.0 Watt at 60 kHz |
| Pulse frequency range: | 1 Hz to 100 kHz |
| Pulse length: | <30 ns up to 60 kHz |
| M2: | <1.3 (TEM00) (wave mode) |
| Polarization: | >100:1, horizontal |
| Beam diameter (exit): | 3.5 mm at 1/e2 |
| Beam divergence at full angle: | <0.3 mrad |

ZnO layers for the sample were about 2 μm thick deposited on glass by LP-CVD process.

Laserscribing or layer structuring processes for coated substrates with ZnO deposited by other methods (sputtering, etc.) or other TCO materials with similar absorption characteristics to ZnO could also benefit from the described process of the invention as well.

The invention has been described hereinabove using specific examples and embodiments; however, it will be understood by those skilled in the art that various alternatives may be used and equivalents may be substituted for elements and/or steps described herein, without deviating from the scope of the invention. Modifications may be necessary to adapt the invention to a particular situation or to particular needs without departing from the scope of the invention. It is intended that the invention not be limited to the particular implementations and embodiments described herein, but that the claims be given their broadest interpretation to cover all embodiments, literal or equivalent, disclosed or not, covered thereby.

1. A method for manufacturing a thin-film solar cell comprising the steps of:
providing a conducting layer on a substrate;
applying a laser beam to said conducting layer to scribe portions of said conducting layer through to said substrate to form a trench through and along some portion of said conducting layer, wherein a substantial portion of the energy of said laser is absorbed by said conducting layer, such that said applying evaporates a substantial portion of said conducting layer in contact with said laser beam to form substantially smooth walls of said trench;
providing one or more active layers over said conducting layer, and
providing an additional conducting layer on said one or more active layers.

2. The method of claim 1, wherein said laser beam has a wavelength of less than 400 nm.

3. The method of claim 2, wherein said conducting layer includes ZnO and said laser beam has a wavelength of about 355 nm.

4. The method of claim 1, wherein said applying a laser beam step uses said trench to separate said conducting layer into a plurality of separate conducting layers that are electrically isolated from each other by an amount greater than 100 kΩ/m.

5. The method of claim 4, wherein said trench has a width of less than 20 μm.

6. The method of claim 4, wherein said trench has a width of about 15 μm or less.

7. The method of claim 1, wherein said trench has a width of less than 20 μm.

8. The method of claim 1, wherein said trench has a width of about 15 μm or less.

9. The method of claim 1, wherein said step of applying said laser beam to said conducting layer to scribe portions of said conductor layer through to said substrate to form said trench is performed at a scribe velocity of about 20 m/min or more.

10. The method of claim 9, wherein said scribe velocity is greater than 25 m/min.

11. The method of claim 9, wherein said scribe velocity is greater than 40 m/min.

12. The method of claim 1, wherein said applying said laser beam step uses a laser including a lens having a focal length of about 63 mm.

13. The method of claim 1, wherein said applying said laser beam step uses a laser of about 8 watts or more of power.

14. The method of claim 1, wherein said applying said laser beam step forms a separate conducting layer for each of a plurality of said solar cells on said substrate, and wherein a separate conducting layer of one of said plurality of solar sells is electrically connected to the additional conducting layer of an adjacent one of said plurality of solar cells, thereby forming series connected solar cells.

15. A method for manufacturing a thin-film solar cell comprising the steps of:
providing a conducting layer including ZnO on a substrate;
applying an ultraviolet laser beam to said conducting layer to scribe portions of said conductor layer through to said substrate to form a trench through and along some portion of said conducting layer;
providing one or more active layers over said conducting layer, and
providing an additional conducting layer on said one or more active layers.

16. The method of claim 15, wherein said laser beam has a wavelength of less than 400 nm.

17. The method of claim 16, wherein said laser beam has a wavelength of about 355 nm.

18. The method of claim 15, wherein said applying a laser beam step uses said trench to separate said conducting layer into a plurality of separate conducting layers that are electrically isolated from each other by an amount greater than 100 kΩ/m.

19. The method of claim 15, wherein said trench has a width of less than 20 μm.

20. The method of claim 15, wherein said trench has a width of about 15 μm or less.

21. The method of claim 15, wherein said step of applying said laser beam to said conducting layer to scribe portions of said conductor layer through to said substrate to form said trench is performed at a scribe velocity of about 20 m/min or more.

22. The method of claim 21, wherein said scribe velocity is greater than 25 m/min.

23. The method of claim 21, wherein said scribe velocity is greater than 40 m/min.

24. The method of claim 15, wherein said applying said laser beam step uses a laser including a lens having a focal length of about 63 mm.

25. The method of claim 15, wherein said applying said laser beam step uses a laser of about 8 watts or more of power.

26. The method of claim 1, wherein said applying said laser beam step forms a separate conducting layer for each of a plurality of said solar cells on said substrate, and wherein a separate conducting layer of one of said plurality of solar sells is electrically connected to the additional conducting layer of an adjacent one of said plurality of solar cells, thereby forming series connected solar cells.

27. A solar module comprising:
a substrate;
a first conducting layer including ZnO covering some portion of said substrate, wherein said conducting layer has a plurality of first trenches scribed through to the underlying substrate to form a plurality of separate conducting layer portions from said conducting layer separated from each other by said plurality of first trenches;
one or more active layers covering some portion of said conducting layer, wherein said one or more active layers has a plurality of second trenches scribed through to the underlying conducting layer to form a plurality of separate active layer portions from said one or more active layers separated from each other by said plurality of second trenches, and wherein each of said plurality of separate active layer portions covers a portion of a corresponding one of said plurality of separate conducting layer portions; and
a plurality of separate second conducting layers each covering some portion of a corresponding one of said separate active layer portions, wherein
a plurality of series connected solar cells on said substrate each include one of said separate second conducting layers, the corresponding one of said separate active layer portions and the corresponding one of said separate first conducting layer portions, and wherein
said solar cells are series connected by electrically connecting the second conducting layer of one of said solar cells to the first conducting layer portion of an adjacent one of said solar cells.

28. The solar module of claim 27, wherein an overall second conducting layer has a plurality of third trenches scribed through to the underlying active layers to form said plurality of separate second conducting layers.

29. The solar module of claim 28, wherein each of said solar cells has at least one of said first trenches parallel and adjacent to one of said second trenches, and wherein said one of said second trenches is also parallel and adjacent to one of said third trenches, and further wherein all of said at least one of said first trenches, said one of said second trenches, and said one of said third trenches fall within a total width of about 140 μm.
